(19) United States
(12) Patent Application Publication
(10) Pub. No.: US 2008/0250302 A1
(43) Pub. Date: Oct. 9, 2008

(54) Convolutional Encoder and the Encoing Method Thereof

(75) Inventors: Gang Wu, Shanghai (CN); Yueheng Li, Shanghai (CN)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,186

(22) PCT Filed: Mar. 7, 2005
(86) PCT No.: PCT/IB2005/050829

§ 371 Date: Sep. 22, 2006

(30) Foreign Application Priority Data
Mar. 25, 2004 (CN) 200410031344.5

(51) Int. Cl. H03M 13/23

(52) U.S. Cl. 714/786; 714/E11.021

(57) ABSTRACT

A convolutional encoder and the encoding method thereof, wherein the encoding method includes steps of: generating convolutional code according to the predefined criteria and with reference to the encoder's predefined convolutional encoding rate and constraint length; processing the data to be transmitted by using the convolutional code so that the coded data are suitable for propagation in multipath fading channel with Rayleigh fading, wherein the predefined criteria is to maximize the sum of Euclidean distance between each branch along the shortest error event path and each corresponding branch along the correct decoding path, and the shortest error event path is the decoding path having the minimum branches of non-zero Euclidean distance compared with the correct decoding path.

### FIELD OF THE INVENTION

The present invention relates generally to a communication method and apparatus, specifically to a convolutional encoder and the encoding method, and more particularly, to a convolutional encoder and its encoding method for use in Rayleigh fading channel.

### BACKGROUND ART OF THE INVENTION

Convolutional encoders and the encoding method thereof are very important for combating the fading and noise interferences and improving system performance in current 3GPP 3.84/1.28 Mcps TDD systems.

FIG. 1 illustrates a convolutional encoder adopted in current 3GPP TDD specification. With regard to the convolutional encoder as displayed in the figure, the constraint length is defined to be 9 (that is, the bit number for recording the state about the input bits in the encoder) in 3GPP TDD specification, the encoding rate is ⅓ (that is, one input signal corresponds to three output signals), and the corresponding generator polynomial is G₀,G₁,G₂: 557,663,771, wherein 557, 663 and 771 are all octal.

FIG. 2 illustrates the link layer model of the DCH (Dedicated Channel) for carrying speech traffic in simulation environment in 3GPP communication system wherein the network system acts as the transmitter side, the mobile terminal acts as the receiver side and channel encoder 100 can employ the convolutional encoder shown FIG. 1.

A brief introduction will be given below to the working principle as how channel encoder 100 cooperates with other components to combat channel fading and noise interferences during the procedure of transferring speech traffic over the DCH.

First of all, the information data that can be shared by multiple UEs or one UE, are encoded in channel encoder 100. After being processed by the convolutional encoder whose generator polynomial is G₀,G₁,G₂: 557,663,771, the encoded information data will be interleaved (inter-frame) by the first interleaver 102 and then sent into radio frame segmentation module 104 where the data are divided into two sub-frames of one radio frame. Next, after each frame data is punctured by rate matching module 106 and added with DCCH (Dedicated Control Channel) information data by service multiplexing module 108, the interleaved (intra-frame) information data can be obtained from the second interleaver 110. After being added with TFCI (Transport Format Combination Indicator) and TPC (Transmitter Power Control) information, the interleaved data are mapped into symbols in symbol mapper 114. Then, after being spread by OVSF spreader 116 and scrambled by scrambler 118, the spread data are embedded with midamble information to build timeslots that can meet the requirements of the DPCH (Dedicated Physical Channel). The symbols in multiple timeslots formed at the transmitter side in the above way are sent to the wireless channel after being modulated by modulating module 122 and combined by combining module 124, and then arrive at the receiver side via the wireless channel of multiple propagation paths.

At the receiver side, the radio signal received by match filtering & over-sampling module 300 usually bears AWGN (Additive White Gaussian Noise) and has multipath fading characteristic, wherein time variance and frequency selectivity are the main features. The discrete time signal generated by match filtering & over-sampling module 300 is fed into channel estimation unit 302 and ACD (Active Codes Detection) module 304, for generating channel estimation information and ACD information. By using the channel estimation information and ACD information, JD module 306 performs JD (Joint Detection) on the discrete time signal. Then, the processed signal is outputted into symbol de-mapper 308 for de-mapping, into TFCI & TPC removing module 310 for removing the TFCI and TPC information, into the first de-interleaver 312 for intra-frame de-interleaving, into service demultiplexing module 314 for extracting the information data of the DCH and the speech traffic data, into zero embedding module 316 for de-punching, into radio frame combining module 318 for combining the speech traffic data divided into two sub-frames, into the second de-interleaver 320 for inter-frame de-interleaving and into channel decoder 322 to get the speech data sent from the transmitter side through decoding.

In the above wireless communication system, convolutional encoder is adopted in channel encoder 100 at the transmitter side to perform convolutional encoding on the speech data to be transmitted, so channel decoder 322 at the receiver side can employ the decoding method corresponding to the encoding method used by channel encoder 100, to recover the speech traffic data sent by the transmitted side from the received signal and effectively reduce the probability of error code generated from the received signal, thus the communication system performance can be improved a lot. The BER (Bit Error Rate) or BLER (Block Error Rate) of the received signal can be obtained by detecting the speech traffic data sent from the transmitter side and the speech traffic data recovered by the channel decoder at the receiver side in a BER/BLER detecting module 324.

However, the convolutional coder used in the above communication system is designed for particular use in BPSK (Binary Phase Shift Keying) modulation scheme and AWGN propagation channel, and accordingly the communication system can achieve the best performance just in the case where BPSK is used to modulate the signal to be sent and there is only Gaussian noise in the propagation channel.

In fact, QPSK (Quadrature Phase Shift Keying) modulation scheme is used in 3GPP 3.84/1.28 Mcps TDD communication systems, and multipath fading channels are often encountered and each path's fading can be approximated as Rayleigh fading in the practical communication environments. In this way, the best performance can't be achieved if we employ the convolutional encoder of FIG. 1 in practical 3GPP 3.84/1.28 Mcps TDD communication systems.

### SUMMARY OF THE INVENTION

An object of the present invention is to provide a convolutional encoder and the encoding method thereof, wherein through analyzing the integration effects of QPSK modulation scheme and multipath fading channel upon the communication system, we put forward an optimized convolutional encoder and the encoding method for particular use in 3GPP 3.84/1.28 Mcps TDD communication systems.

An encoding method is proposed in the present invention, comprising: setting the encoder's convolutional encoding rate and constraint length according to the relevant specification in communication protocol; generating convolutional code according to the predefined criteria, under said convolutional encoding rate and constraint length; processing the data to be sent by using the convolutional code so that the encoded data are suitable for transmission in multipath fading channel with Rayleigh fading. Wherein the predefined criteria is to maximize the sum of Euclidean distance between each branch along the shortest error event path and each corresponding branch along the correct decoding path, wherein the shortest error event path is the decoding path having the minimum branches of non-zero Euclidean distance compared with the correct decoding path.

A convolutional decoding method is proposed in the present invention, comprising: receiving the convolutional encoded data which are generated according to the predefined criteria and transferred via multipath fading channel; setting the decoder's corresponding convolutional decoding rate and constraint length, according to the convolutional code; decoding the received data under the convolutional decoding rate and constraint length so that the decoded data can be gotten rid of Rayleigh fading during propagation via the multipath fading channel. Wherein the predefined criteria is to maximize the sum of Euclidean distance between each branch along the shortest error event path and each corresponding branch along the correct decoding path, wherein the shortest error event path is the decoding path having the minimum branches of non-zero Euclidean distance compared with the correct decoding path.

Other objects and attainments together with a fuller understanding of the invention will become apparent and appreciated by referring to the following descriptions and claims taken in conjunction with the accompanying drawings.

### BRIEF DESCRIPTION OF THE DRAWINGS

For a detailed description of the preferred embodiments of the invention, reference will now be made to the accompanying drawings in which like reference numerals refer to like parts, and in which:

FIG. 1 illustrates the architecture of the convolutional encoder adopted in current 3GPP TDD specification;

FIG. 2 illustrates the link layer model of the DCH in current 3GPP TDD communication system;

FIG. 3A illustrates the architecture of the convolutional encoder in accordance with an embodiment of the present invention;

FIG. 3B is the trellis diagram illustrating the convolutional encoder in accordance with an embodiment of the present invention;

FIG. 4 illustrates the comparison between the performance of the convolutional encoder in accordance with an embodiment of the present invention and that of existing convolutional encoder in TD-SCDMA downlink system under three propagation conditions as recommended in 3GPP specification;

FIG. 5 illustrates the comparison between the performance of the convolutional encoder in accordance with an embodiment of the present invention and that of existing convolutional encoder in TD-SCDMA downlink system under the propagation condition as proposed in ITU standard.

### DETAILED DESCRIPTION OF THE INVENTION

The convolutional encoder proposed in the present invention is designed based on the QPSK modulation scheme in 3GPP 3.84/1.28 Mcps TDD communication system and the effect of Rayleigh fading upon the signal during multipath propagation, so it is very necessary to explain the design criteria of the proposed convolutional encoder before describing the convolutional encoder in the present invention in conjunction with accompanying drawings.

In order to describe clearly the design criteria of the proposed convolutional encoder, we represent the received signal in chip case as the matrix expression:

r=Ad+n (1)

where d=[d^{(1)T},d^{(2)T}, . . . , d^{(N)T}]^{T} is the data vector for all active UEs in one data field; N is the symbol number transmitted in the data field; [.]^{T} represents transposition operation on the matrix; d^{(a)}=[d₁^{(a)}, d₂^{(a)}, . . . , d_{M}^{(a)}]^{T}, n=1, 2, . . . , N, is the data vector of all active UEs belonging to the same symbol label; M is the number of active channelisation codes; matrix n is the noise vector corrupting the received signal.

The structure of generalized channel matrix A can be shown as:

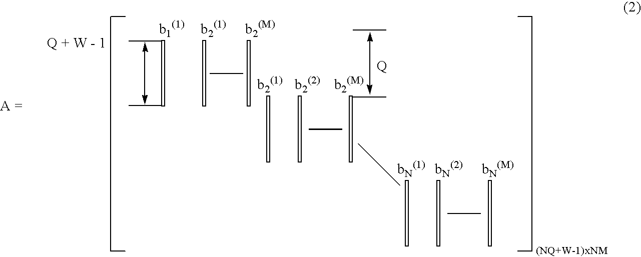

where each shadowed rectangle represents one column vector, for example, bₙ^{(m)}=h^{(m)}*c^{(m)} (1≦m≦M, 1≦n≦N) is the convolution of channel impulse response vector h^{(m)} of active code m and its affiliated OVSF code chip vector c^{(m)}; Q is the spreading factor and w is the maximum time delay of estimated or existed propagation path in chip unit.

The propagation channel parameter h^{(m)} in above equation (2) is usually estimated from the pilot sequence “midamble” embedded in the TS (timeslot). The estimation of the channel impulse response can be written as:

ĥ=M⁻¹·r (3)

M in equation (3) is a square right circulated matrix of the pilot sequence, and [·]⁻¹ represents inverse operation on the matrix.

Based on the estimated propagation channel parameter h^{(m)} and the detected active codes, JD algorithm such as ZF-BLE will be performed on the received signal r. The data vector in the data field after JD algorithm is executed can be expressed as:

\hat{d}=(A^{H}A)⁻¹·A^{H}·r (4)

Since the signal will have some fading during propagation and is subject to interference from noise signal, the detected data vector \hat{d} is very likely to be misjudged, that is, there is some difference between the detected data vector \hat{d} and the correct data vector d.

The object of designing convolutional encoders for encoding the signal to be transmitted is to minimize the error probability of the detected data vector \hat{d} when JD algorithm is performed on the received radio signal at the receiver side.

To realize the object of the convolutional encoding, a design criteria for convolutional encoder is put forward in the present invention, to maximize the statistical sum of Euclidean distance between each branch along the shortest error event path and each corresponding branch along the correct decoding path. This design criteria is proposed on basis of considering the following factors:

### 1. Mutual Independence for Each Transmitted Symbol

There are two kinds of interleavers in 3GPP 3.84/1.28 Mcps TDD downlink system, i.e. intra-frame interleaver and inter-frame interleaver, which can ensure nearly ideal interleaving, especially in fast fading channel where the propagation of each datum in the channel is independent after being ideally interleaved. In other words, channel impulse response h^{(m)} in equation (2) is nearly independent for each transmitted symbol.

### 2. Each Path in the Multipath Channel is Rayleigh Fading Channel

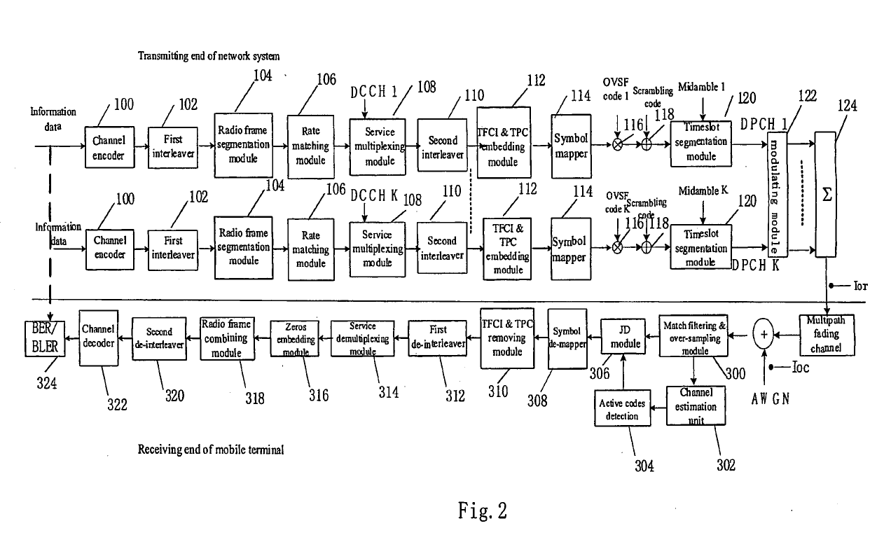

In 3GPP 3.84/1.28 Mcps TDD downlink system, the wireless channel for transferring signals is usually multipath and each path is Rayleigh fading. For Rayleigh fading channel after ideal interleaving, the simulation experiment in FIG. 2 indicates that the bigger is the product of Euclidean distance between each branch along the shortest error event path and each corresponding branch along the correct decoding path, the less will be the error probability of the JD processed data, that is, the lower will be the BER or BLER obtained from BER/BLER detecting module 324. Wherein the shortest error event path is the decoding path with the minimum branches of non-zero Euclidean distance compared with the correct decoding path, which can be found with method like Viterbi decoding. Additionally, the computation can be simplified by replacing the above product of Euclidean distance with the sum of Euclidean distance.

### 3. QPSK Modulation

In 3GPP 3.84/1.28 Mcps TDD downlink system, QPSK modulation scheme is usually adopted for speech traffic communication, i.e. mapping the two input bits into a phase point (a phase point is a symbol) on the trellis diagram every time when the data to be transmitted in bit form are mapped into the trellis diagram. Since the convolutional encoding rate is defined to be ⅓ in 3GPP 3.84/1.28 Mcps TDD specification, when the coded data are mapped into the trellis diagram, 3-bit output of the convolutional encoder corresponds to 2-bit input under QPSK modulation scheme. Therefore, only by taking account of the outputs of all decoding paths, can we get the Euclidean distance from the correct decoding path, that is to say the statistical sum of Euclidean distance should be considered.

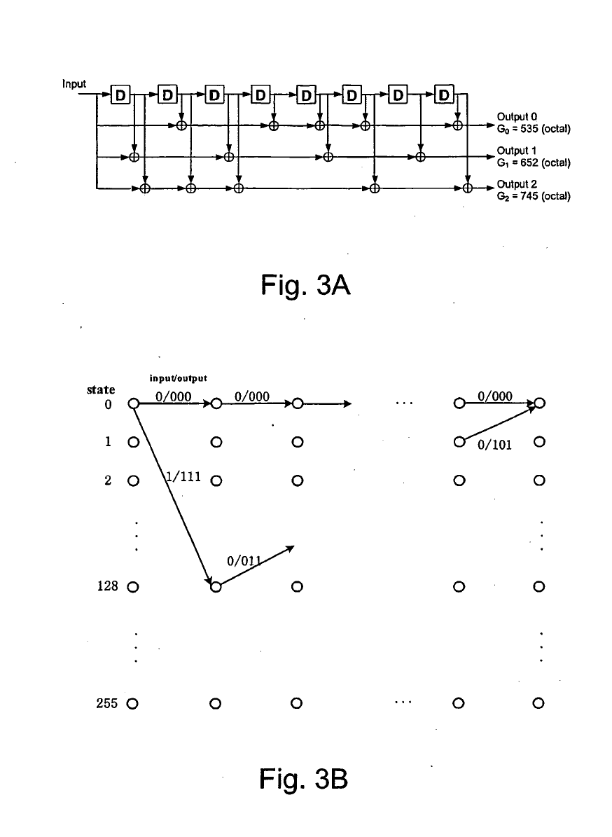

FIG. 3A illustrates a convolutional encoder in the present invention designed on the basis of the above criteria. As shown in FIG. 3A, the constraint length and convolutional encoding rate of the convolutional encoder are defined to be 9 and ⅓ respectively in 3GPP TDD specification. With regard to the above design criteria, the corresponding convolutional code of the convolutional encoder is G₀,G₁,G₂: 535,652,745, wherein 535, 652 and 745 are all octal. According to the architecture of the convolutional encoder, the corresponding trellis diagram can be referred to FIG. 3B. In FIG. 3B, the states from zero to 255^{th} are denoted by the empty rounds from 1^{st} to 256^{th} rows, and the time is increasing from left to-right columns. The branch from one state to another in FIG. 3B is decided by the outputted coded signal corresponding to the input signal. For instance, when the initial position of branch 1/111 (1/111 is the input signal/output signal of the convolutional encoder) in FIG. 3B is in zero state, it means all shift registers D in FIG. 3A are zero in the initial state. When 1 is inputted into the convolutional encoder in FIG. 3A, the output signal of the convolutional encoder is computed to be 111, and at this moment branch 1/111 in FIG. 3B transfers to state 128 from the initial state 0, as illustrated by the arrowhead of branch 1/111.

When mapping the coded signal generated by adopting the convolutional encoder in FIG. 3A into the QPSK trellis diagram, we can compute and get the statistical sum of Euclidean distance between each branch along the shortest error event path and each corresponding branch along the correct decoding path Σd²=44, where d_{E} denotes Euclidean distance.

Computation of Euclidean distance will be explained in the following section, by exemplifying the first branch 1/111 along the shortest error event path and the corresponding first branch 0/000 along the correct decoding path in FIG. 3B.

When bits are mapped into the QPSK trellis diagram, a 2D coordinate point corresponds to two bits in the trellis diagram. If binary number 00 corresponds to coordinate point (0, j), 01 to (1, 0), 10 to (−1, 0) and 11 to (0, −j), the first two bits 11 of the output signal 111 from branch 1/111 correspond to (0,−j) in the trellis diagram, the first two bits 00 of the output signal from branch 0/000 correspond to (0, j), and the distance \sqrt{|0−0|²+|j−(−j)|²}between the two coordinate points (0, −j) and (0, j) is Euclidean distance between the two branches. Since one coordinate point in the QPSK trellis diagram corresponds to two bits, the output signal from each branch of the shortest event path is required to be combined to correspond to the combined output signal from each branch of the correct decoding path in such a way that two bits form a group and according to the position in the trellis diagram where each group of bits are mapped, for computation of Euclidean distance of each group. The output signals of all branches are combined, then Euclidean distance of each group of bits is computed and the Euclidean distance of each group is summed, so it's also called statistical sum of Euclidean distance. Through computation with the above method, we can get the above statistical sum of Euclidean distance Σd_{E}²=44.

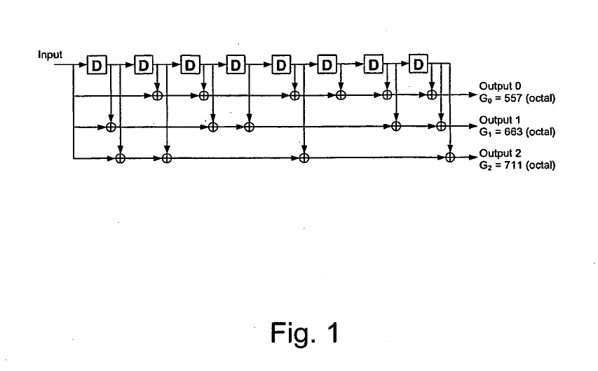

In accordance with the above method, when the coded signal generated by adopting the convolutional encoder in FIG. 1 is mapped into the QPSK trellis diagram, the statistical sum of Euclidean distance between each branch along the shortest error event path and each corresponding branch along the correct decoding path can be computed as Σd_{E}²=36.

The statistical sum of Euclidean distance between each branch along the shortest error event path and each corresponding branch along the correct decoding path, computed with reference to the proposed convolutional encoder, is much higher than that of the convolutional encoder adopted in current 3GPP TDD system, and thus application of the proposed convolutional encoder can achieve better system performance, which will be further validated in later simulation experiment.

The simulation experiment is accomplished on the basis of 3GPP TDD downlink system and the parameters used in the simulation experiment are shown in Table.1.

TABLE 1
simulation parameters in 3GPP TDD downlink system

| Parameter/Feature | Value/Expression | Note |
|---|---|---|
| Chip rate | 1.28 Mcps | |
| Modulation scheme | QPSK | |
| Spreading Factor | 16 | |
| Nominal Channel | 1.6 MHz/Carrier | |
| Spacing | | |
| Burst Format | 1 burst type | |
| Radio Frame Length | 10 ms (divided into 2 sub-frames) | |
| Sub-frame length | 5 ms | |
| Number of traffic | 7 | |
| timeslots | | |
| Timeslot length (us) | 675 | |
| Chip length (ns) | 781.25 | |
| Pilot aided detection | Default Midamble (K = 8) | |
| Channel coder | Convolutional code with 1/3 rate, | |
| | constraint length 9. | |
| Interleaver | 20 ms block interleaving | |
| Synchronization | Perfect synchronization | |
| aspect | | |
| Service mapping | Multi-code, multi-slot combination | |
| Number of samples | 8 | |
| per chip | | |
| Numerical precision | Floating point simulations | |
| Channel estimation | ML channel estimation with FFT | |
| | implementation | |
| BLER calculation | Calculated by comparing with | |
| | transmitted and received frames. | |
| DCCH model | Random symbols transmitted | No evaluation |
| | | in the receiver |
| DPCH model | Random symbols transmitted | The same chip |
| | | energy for each |
| | | channel |
| Other L1 parameters | As Specified in latest L1 | |
| | specifications | |
| JD algorithm | ZF-BLE | |
| Communication | Five 12.2 Kbit/s UEs in the same | |
| scenario | timeslot | |

Table.2 lists the wireless propagation channel parameters for testing multipath fading environments under the three channel conditions recommended by 3GPP.

TABLE 2
Propagation conditions for multipath fading environments

| Case 1, speed 3 km/h | | Case 2, speed 3 km/h | | Case 3, 120 km/h | |
|---|---|---|---|---|---|
| | Average | | Average | | Average |
| Relative | Power | Relative | Power | Relative | Power |
| Delay | attenuation | Delay | attenuation | Delay | attenuation |
| [ns] | [dB] | [ns] | [dB] | [ns] | [dB] |
| 0 | 0 | 0 | 0 | 0 | 0 |
| 2928 | −10 | 2928 | 0 | 781 | −3 |
| | | 12000 | 0 | 1563 | −6 |
| | | | | 2343 | −9 |

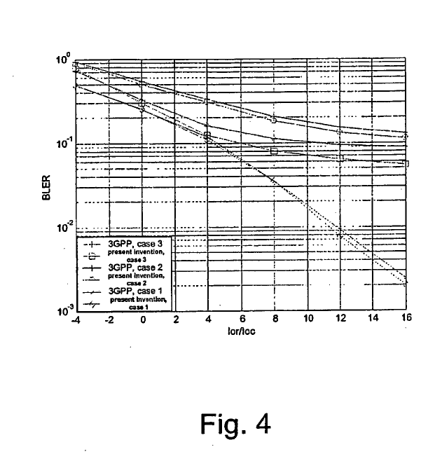

Under the three conditions, when the current 3GPP convolutional encoder in FIG. 1 and the convolutional encoder in FIG. 3A in accordance with the present invention are adopted, the simulation results are shown in FIG. 4.

In FIG. 4, the ordinate represents the logarithm coordinate of the BLER and the abscissa represents lor/loc, wherein lor is the receive power spectral density measured at the UE antenna and loc is the power spectral density of a band-limited white noise source measured at the UE antenna. FIG. 4 illustrates the system performance curve for the convolutional encoder in the present invention as shown in FIG. 3A and current 3GPP convolutional encoder as shown in FIG. 1 under three propagation conditions. As displayed in FIG. 4, when BLER=10⁻¹, the system performance for the proposed convolutional encoder can achieve nearly 4 dB improvement in the third case where the UE has the fastest speed.

Table.3 lists the wireless propagation channel parameters recommended by ITU for testing multipath fading environments.

TABLE 3
Propagation conditions for multipath fading environments

| ITU Pedestrian A | | ITU Pedestrian B | | ITU vehicular A | | ITU vehicular A | |
|---|---|---|---|---|---|---|---|
| Speed 3 km/h | | Speed 3 Km/h | | Speed 30 km/h | | Speed 120 km/h | |
| (PA3) | | (PB3) | | (VA30) | | (VA120) | |
| | Average | | Average | | Average | | Average |
| Relative | Power | Relative | Power | Relative | Power | Relative | Power |
| Delay | attenuation | Delay | attenuation | Delay | attenuation | Delay | attenuation |
| [ns] | [dB] | [ns] | [dB] | [ns] | [dB] | [ns] | [dB] |
| 0 | 0 | 0 | 0 | 0 | 0 | 0 | 0 |
| 110 | −9.7 | 200 | −0.9 | 310 | −1.0 | 310 | −1.0 |
| 190 | −19.2 | 800 | −4.9 | 710 | −9.0 | 710 | −9.0 |
| 410 | −22.8 | 1200 | −8.0 | 1090 | −10.0 | 1090 | −10.0 |
| | | 2300 | −7.8 | 1730 | −15.0 | 1730 | −15.0 |
| | | 3700 | −23.9 | 2510 | −20 | 2510 | −20 |

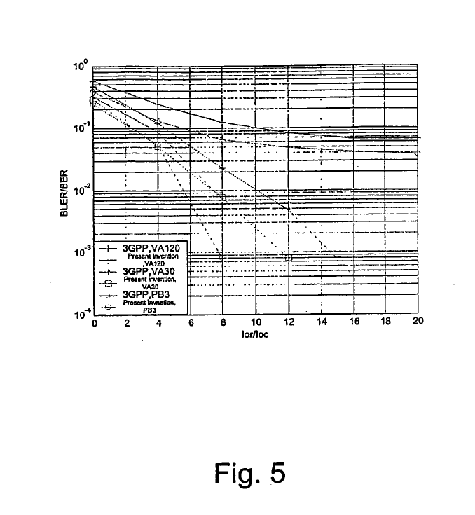

Under the channel conditions as shown in Table.3, when the current 3GPP convolutional encoder in FIG. 1 and the convolutional encoder in FIG. 3A in accordance with the present invention are adopted, the simulation results can be shown in FIG. 5.

In FIG. 5, the ordinate represents the logarithm coordinate of the BLER and the abscissa represents lor/loc, wherein lor is the receive power spectral density measured at the UE antenna and loc is the power spectral density of a band-limited white noise source measured at the UE antenna. FIG. 5 illustrates the system performance curve for the convolutional encoder in the present invention as shown in FIG. 3A and current 3GPP convolutional encoder as shown in FIG. 1 under different propagation conditions. As displayed in FIG. 5, when BLER=10⁻¹, the system performance for the proposed convolutional encoder can achieve nearly 4 dB improvement in the case of VA120; and when BLER=10⁻², the system performance for the proposed convolutional encoder can achieve nearly 1.5 dB and 1 dB respectively in the case of VA30 and PB3.

The simulation results as shown in FIG. 4 and FIG. 5 further support the conclusion that the convolutional encoder constructed with the design criteria of the present invention can attain remarkable improvement in combating Rayleigh fading and reducing noise interference compared with the convolutional encoder used in current 3GPP TDD system.

In accordance with the design criteria in the present invention to maximize the statistical sum of Euclidean distance between each branch along the shortest error event path and each corresponding branch along the correct decoding path, we can get the convolutional code G₀, G₁, G₂: 535, 652, 745, and other convolutional codes as well, which can be referred to Table.4. The generator polynomial for each convolutional code as listed in Table.4 is octal and the computed statistical sum of Euclidean distance is Σd_{E}²=44 for all. Better system performance can be achieved by using any convolutional code in Table.4 for encoding the signal to be transmitted than by using the convolutional codes in current 3GPP TDD system.

TABLE 4
convolutional codes provided in the present invention

| Convolutional codes | G₀ | G₁ | G₂ |
|---|---|---|---|
| I | 535 | 652 | 745 |
| II | 535 | 652 | 715 |
| III | 527 | 652 | 761 |
| IV | 525 | 676 | 725 |
| V | 525 | 676 | 724 |
| VI | 535 | 653 | 725 |
| VII | 535 | 653 | 724 |

In the procedure of obtaining each convolutional code in accordance with the above design criteria in the present invention, considerations should go to an objective that the coded signal is required to be able to overcome impact from Rayleigh fading channel during propagation, and another objective that the coded signal should be able to combat impact from Gaussian noise channel to some extent.

The are many design criterions for radio signals to battle Gaussian noise during propagation, for instance, the method of using the coded signal with Hamming distance higher than a certain threshold.

The simulation results show that each convolutional code in the present invention as listed in above Table.4 can achieve good system performance at overcoming Rayleigh fading and Gaussian noise.

The above description dwells on the design criteria of the proposed convolutional codes and each convolutional code derived from the design criteria. When the radio signal processed with the proposed convolutional code arrives at the receiver side after multipath propagation, the decoder in the receiver can set the corresponding convolutional decoding rate and constraint length according to the specification of 3GPP TDD system, and decode the received data by employing the decoding method and decoding code corresponding to those in the transmitter's convolutional encoder, thus to get the output signal that can overcome Rayleigh fading during multipath propagation.

### BENEFICIAL RESULTS OF THE INVENTION

With reference to the above detailed description of the preferred embodiments of the present invention in conjunction with accompanying drawings, through taking account of the integration effects of QPSK modulation scheme and multipath fading channel upon the communication system into the design of the encoder and the encoding method, the proposed convolutional encoder and encoding method can effectively overcome Rayleigh fading, reduce noise interference and improve system performance when applied in 3GPP 3.84/1.28 Mcps TDD communication system.

No matter being applied in the channel encoding module at the transmitter side or in the channel decoding module at the receiver side, the proposed convolutional encoding method and the corresponding decoding method don't require significant modifications to current equipments, and meanwhile the communication system performance can be boosted greatly.

Moreover, the convolutional encoding method and the corresponding decoding method as proposed in the present invention are applicable to 3.84 Mcps TDD system, as well as 1.28 Mcps TDD system, such as TD-SCDMA system.

It is to be understood by those skilled in the art that the convolutional encoding method and the corresponding decoding method for use in 3GPP TDD systems as disclosed in this invention can be made of various modifications without departing from the spirit and scope of the invention as defined by the appended claims.

1. An encoding method, comprising:
generating convolutional code according to a predefined criteria and with reference to encoder's predefined convolutional encoding rate and constraint length;
processing data to be transmitted by using the convolutional code so that the coded data are suitable for propagation in multipath fading channel with Rayleigh fading.

2. The method according to claim 1, further comprising:
setting said convolutional encoding rate and constraint length according to a specification in a communication protocol.

3. The method according to claim 1, wherein said predefined criteria is to maximize the sum of Euclidean distance between branches of a predefined number along the shortest error event path and the corresponding branches of the predefined number along a correct decoding path, and the shortest error event path is a decoding path having the minimum branches of non-zero Euclidean distance compared with the correct decoding path.

4. The method according to claim 3, wherein said branches of the predefined number are all the branches constructing the shortest error event path and all the branches constructing the correct decoding path.

5. The method according to claim 4, wherein said sum of Euclidean distance is statistical sum of Euclidean distance when QPSK modulation scheme is adopted in said communication protocol.

6. The method according to claim 5, wherein said coded data are also suitable for propagation in AWGN channel with Gaussian noise.

7. The method according to claim 5, wherein said convolutional code can be any one of the following code:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

8. A convolutional decoding method, comprising:
receiving data processed with convolutional code generated according to a predefined criteria via multipath fading channel;
decoding the received data by using convolutional decode corresponding to the convolutional code, so that the decoded data can be gotten rid of Rayleigh fading during propagation via the multipath fading channel.

9. The method according to claim 8, wherein said predefined criteria is to maximize sum of Euclidean distance between branches of a predefined number along the shortest error event path and corresponding branches of the predefined number along a correct decoding path, and the shortest error event path is a decoding path having the minimum branches of non-zero Euclidean distance compared with the correct decoding path.

10. The method according to claim 8, wherein said branches of the predefined number are all branches constructing the shortest error event path and all branches constructing the correct decoding path.

11. The method according to claim 10, wherein said sum of Euclidean distance is statistical sum of Euclidean distance when said received data adopt QPSK modulation scheme.

12. The method according to claim 11, wherein said decoded data can be gotten rid of Gaussian noise during propagation via a AWGN channel.

13. The method according to claim 11, wherein said decode is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

14. An encoder, comprising:
an encoding module, for processing data to be transmitted by using convolutional code so that the coded data are suitable for propagation in multipath fading channel with Rayleigh fading, wherein the convolutional code is generated according to a criteria of maximizing sum of Euclidean distance between each branch along the shortest error event path and each corresponding branch along a correct decoding path, and the shortest error event path is a decoding path having the minimum branches of non-zero Euclidean distance compared with the correct decoding path.

15. The encoder according to claim 14, wherein said sum of Euclidean distance is statistical sum of Euclidean distance when QPSK modulation scheme is adopted in said communication protocol.

16. The encoder according to claim 15, wherein said convolutional code can be any one of the following code:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

17. A decoder, comprising:
a decoding module, for decoding received data processed with convolutional code by using convolutional decode, so that the decoded data can be gotten rid of the Rayleigh fading during propagation via multipath fading channel, wherein the convolutional decode corresponds to the convolutional code and the convolutional code is generated according to a criteria of maximizing the sum of Euclidean distance between each branch along the shortest error event path and each corresponding branch along a correct decoding path, and the shortest error event path is a decoding path having the minimum branches of non-zero Euclidean distance compared with the correct decoding path.

18. The decoder according to claim 17, wherein said sum of Euclidean distance is the statistical sum of Euclidean distance when QPSK modulation scheme is adopted in said communication protocol.

19. The decoder according to claim 18, wherein said decode is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

20. A UE (User Equipment), comprising:
an encoder, for processing data to be transmitted by using convolutional code so that the coded data are suitable for propagation in multipath fading channel with Rayleigh fading, wherein the convolutional code is generated according to a criteria of maximizing the sum of Euclidean distance between each branch along the shortest error event path and each corresponding branch along a correct decoding path, wherein the shortest error event path is a decoding path having the minimum branches of non-zero Euclidean distance compared with the correct decoding path;
a transmitting unit, for transmitting the coded data.

21. The UE according to claim 20, wherein the convolutional code is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

22. The UE according to claim 21, further comprising:
a receiving unit, for receiving data processed with convolutional code from a network system;
a decoder, for decoding the received data by using convolutional decode corresponding to the convolutional code of the network system, so that the decoded data can be gotten rid of the Rayleigh fading during propagation via multipath fading channel, wherein the convolutional code is generated according to a criteria of maximizing the sum of Euclidean distance between each branch along the shortest error event path and each corresponding branch along a correct decoding path, wherein the shortest error event path is a decoding path having the minimum branches of non-zero Euclidean distance compared with the correct decoding path.

23. The UE according to claim 22, wherein said decode is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

24. A network system, comprising:
an encoder, for processing data to be transmitted by using convolutional code so that the coded data are suitable for propagation in multipath fading channel with Rayleigh fading, wherein the convolutional code is generated according to a criteria of maximizing the sum of Euclidean distance between each branch along the shortest error event path and each corresponding branch along a correct decoding path, and the shortest error event path is a decoding path having the minimum branches of non-zero Euclidean distance compared with the correct decoding path;
a transmitting unit, for transmitting the coded data.

25. The network system according to claim 24, wherein said convolutional code is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.

26. The network system according to claim 25, further comprising:
a receiving unit, for receiving data processed with convolutional code from the UE;
a decoder, for decoding the received data by using convolutional decode corresponding to the convolutional code of the UE, so that the decoded data can be gotten rid of the Rayleigh fading during propagation via the multipath fading channel, wherein the convolutional code is generated according to a criteria of maximizing the sum of Euclidean distance between each branch along the shortest error event path and each corresponding branch along a correct decoding path, and the shortest error event path is a decoding path having the minimum branches of non-zero Euclidean distance compared with the correct decoding path.

27. The network system according to claim 26, wherein said decode is any one of the following:
G₀,G₁,G₂: 535,652,745;
G₀,G₁,G₂: 535,652,715;
G₀,G₁,G₂: 527,652,761;
G₀,G₁,G₂: 525,676,725;
G₀,G₁,G₂: 525,676,724;
G₀,G₁,G₂: 535,653,725;
G₀,G₁,G₂: 535,653,724.
